(19) United States
(12) Patent Application Publication
(10) Pub. No.: US 2009/0179315 A1
(43) Pub. Date: Jul. 16, 2009

(54) Semiconductor Die Packages Having Solder-free Connections, Systems Using the Same, and Methods of Making the Same

(76) Inventor: Armand Vincent Jereza, Cebu City (PH)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/014,015

(22) Filed: Jan. 14, 2008

(51) Int. Cl. H01L 23/48; H01L 21/60

(52) U.S. Cl. 257/676; 438/117; 257/E23.078; 257/E21.515

(57) ABSTRACT

Disclosed are spring structures that provide solderless electrical connections in semiconductor die packages. An exemplary spring structure comprises a first portion adapted to make an electrical connection to a conductive region of a semiconductor die, a second portion adapted to make an electrical connection to a conductive region of a leadframe, and a third portion disposed between the first and second portions. During a molding process, the third portion is compressively strained to impart forces to the first and second portions that maintain these portions in contact with the conductive regions of the die and leadframe. After the molding material sets, the third portion remains in a state of compressive strain, and imparts forces on the first and second portions that maintain the electrical connections. The spring structure may be made of less expensive materials, and does not require cleaning, fluxing, or reflowing, thereby reducing manufacturing cost and time.

### CROSS-REFERENCES TO RELATED APPLICATIONS

NOT APPLICABLE

### BACKGROUND OF THE INVENTION

Small semiconductor die packages are widely used in electronic devices, such as computers, cell phones, televisions, appliances, etc. Such a semiconductor die package typically comprises a semiconductor die having its back surface mounted to a leadframe, a plurality of wire bonds that connect pads at the top surface of the die to respective leads of the leadframe, and a molding material disposed over the wire bonds, die, and leadframe. For power transistor applications, where there may only be one to three large pads on the die's top surface, there may be several wire bonds used per pad, and/or a soldered-on die clip may be used to connect a die pad to a lead. There continues to be pressure in the electronics industry to reduce the time and cost of manufacturing semiconductor die packages.

### BRIEF SUMMARY OF THE INVENTION

As part of making their invention, the inventors have recognized that using multiple wire bonds per pad and solder-on die clips adds significant time and costs in manufacturing semiconductor die packages. Multiple wire bonds per pad use significant wire bonding material, which generally comprises expensive gold material, and the solder-on die clips require cleaning, fluxing, and reflowing steps. The solder-on die clips also require the formation of a solderable metal layer on the die pad, which requires an additional processing step. Each of the above processing steps adds time and cost. Also as part of making their invention, the inventors have discovered that the solder-on die clips and the multiple wire bonds per pad can be replaced by an electrically conductive spring structure (e.g., spring clip) that is compressed against a conductive region of the die and a conductive region of a leadframe during the molding process, and held in a compressed state by the solidified molding material to provide an electrical connection between the die and the leadframe. The spring clip provides an electrically conductive structure that has a first portion abutting an electrically conductive region of the die, a second portion abutting an electrically conductive region of the leadframe, and a third portion located between the structure's first and second portions, where the third portion is compressively strained to impart forces to the first and second portions that maintain these portions in contact with the conductive regions of the die and leadframe. The spring clip may be made of less expensive materials, and does not require cleaning, fluxing, or reflowing steps, thereby reducing manufacturing cost and time.

Accordingly, a first general embodiment of the invention is directed to a semiconductor die package comprising a leadframe, a semiconductor die, an electrically conductive structure, and a body of molding material. The leadframe has a first electrically conductive region. The semiconductor die has a first surface, a second surface attached to a portion of the leadframe, and a first electrically conductive region disposed on the die's first surface. The electrically conductive structure has a first portion abutting the die's first electrically conductive region, a second portion abutting the leadframe's first electrically conductive region, and a third portion located between the structure's first and second portions, with the third portion being compressively strained. The body molding material is disposed over at least a portion of the first electrically conductive structure, over at least a portion of the die's first surface, and over at least portions of the leadframe's first and second electrically conductive regions. The body molding material maintains the third portion of the conductive structure in a compressively strained state.

Another general embodiment of the invention is directed to a method for forming a semiconductor die package, the method comprising attaching a semiconductor die to a conductive region of a leadframe, and assembling an electrically conductive structure with the die and leadframe such that a first portion of the electrically conductive structure at least faces a first electrically conductive region of the die, and a second portion of the electrically conductive structure at least faces a first electrically conductive region of the leadframe. The electrically conductive structure has a third portion located between the structure's first and second portions, and the third portion may be placed in a state of compressive strain. The method further comprises applying a force to the electrically conductive structure such that the structure's first portion abuts the die's first conductive region, the structure's second portion abuts the leadframe's first conductive region, and the structure's third portion is compressively strained. The method further comprises disposing a molding material over at least a portion of the electrically conductive structure, at least a portion of the die, and at least a portion of the leadframe. The molding material may be disposed before, during, or after the initiation of the force. The method further comprises maintaining the application of the force while the molding material undergoes a transition from a liquid state to a solid state.

Another general embodiment of the invention is directed to a system, such as an electronic device that comprises a semiconductor die package according to the invention.

These and other embodiments of the invention are described in detail in the Detailed Description with reference to the Figures. In the Figures, like numerals may reference like elements and descriptions of some elements may not be repeated.

### BRIEF DESCRIPTION OF THE DRAWINGS

FIG. 1 is an expanded perspective view of a portion of a first exemplary semiconductor die package according to the present invention, and

FIGS. 2 and 3 are partially assembled perspective views thereof.

FIGS. 4 and 5 are side views the first exemplary semiconductor die package according to the present invention before and during an exemplary molding process according to the present invention.

FIGS. 6 and 7 are top and bottom perspective views of the completed first exemplary semiconductor die package according to the present invention.

FIGS. 8 and 9 are side views of a portion of a second exemplary semiconductor die package according to the present invention before and during an exemplary molding process according to the present invention.

FIGS. 10 and 11 are side views of additional embodiments of the spring structure according to the present invention.

FIG. 12 is a perspective view of a system that comprises a semiconductor die package according to the present invention.

### DETAILED DESCRIPTION OF THE INVENTION

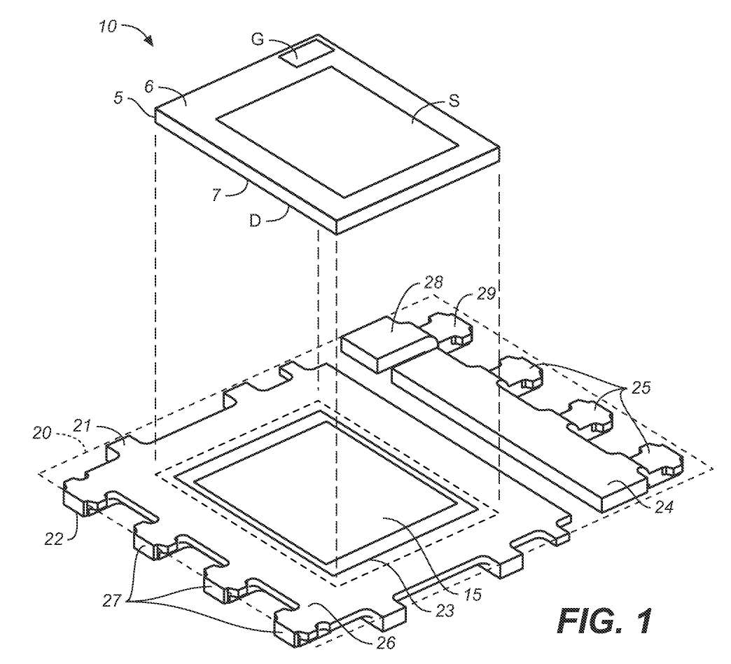

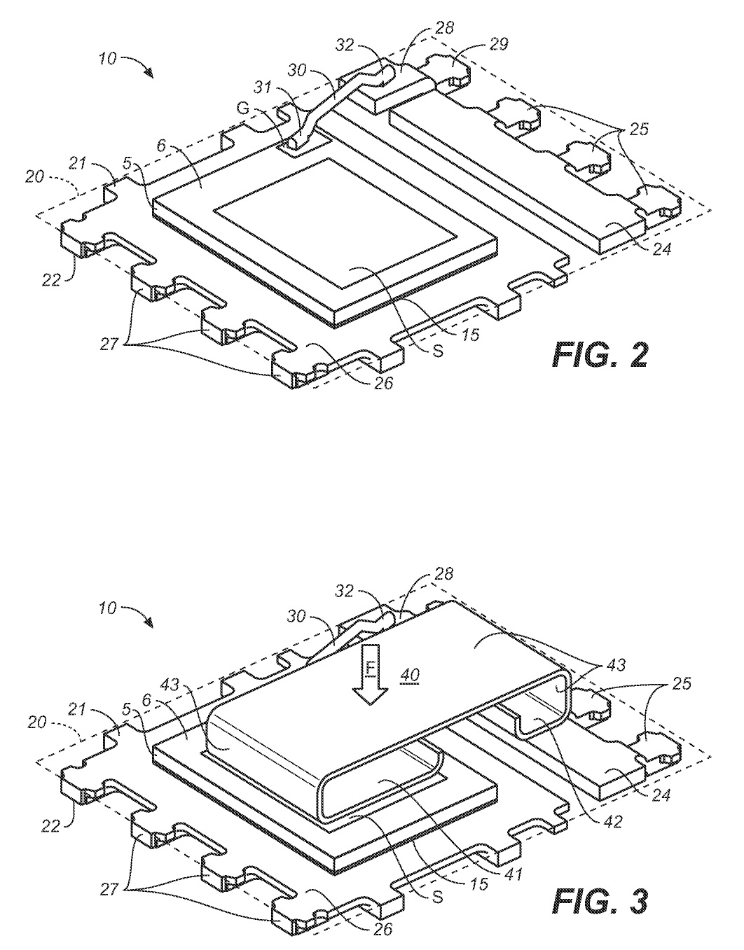

FIG. 1 shows a partial expanded perspective view of a first exemplary semiconductor die package 10 according to the present invention. Semiconductor die package 10 comprises a semiconductor die 5, a leadframe 20, at least one electrically conductive wire-type structure 30 (shown in FIGS. 2-5), and at least one electrically conductive spring structure 40 (shown in FIGS. 3-5). Leadframe 20 may comprise a base layer of copper (Cu) that is coated or alloyed with the following order of metal sub-layers: nickel (Ni), palladium (Pd), and gold (Au). Leadframe 20 has a first electrically conductive region 24, a second electrically conductive region 26, and a third electrically conductive region 28. First electrically conductive region 24 comprises a plurality of end caps 25 (also called tabs) at one of its edges. Similarly, second electrically conductive region 26 comprises a plurality of end caps 27 at one of its edges, and third electrically conductive region 28 comprises at least one end cap 29 at one of its edges. In preferred implementations, electrically conductive regions 24-28 will be encapsulated by a body of electrically-insulating molding material (described in greater detail below), except that the bottom portions of end caps 25-29 will be left exposed by the molding material. These bottom portions of the end caps will serve as electrical connection points for package 10. In some implementations, a substantial portion of the bottom surface of second conductive region 26, or entire bottom surface thereof, may be left exposed by the molding material. Still referring to FIG. 1, semiconductor die 5 has a first surface 6, a second surface 7, a first electrically conductive region S disposed on the die's first surface 6, a second electrically conductive region D disposed on the die's second surface 7, and a third electrically conductive region G disposed on the die's first surface 6. In an exemplary implementation, semiconductor die 5 comprises a vertical power device, preferably a power MOSFET device, having a first conduction terminal (e.g., source) at first conductive regions S, a second conduction terminal (e.g., drain) at second conductive region D, and a modulation terminal (e.g., gate) at third conductive region G. However, semiconductor die 5 may comprise other power devices, such as rectifiers, controlled rectifiers (e.g., SCRs), bipolar transistors, insulated-gate field-effect transistors, etc., and may comprise non-power devices such as digital circuits and analog circuits.

In an exemplary manufacturing method, the second surface 7 of semiconductor die 5 is attached to a portion of leadframe 20 such that die's second conductive region D is attached and electrically coupled to portion 23 of the leadframe's second conductive region 26. A body 15 of conductive adhesive may be used to attach the components. For power devices, adhesive body 15 preferably comprises solder material, which may be initially disposed on region 23 as a preform or solder paste layer, and thereafter reflowed while in contact with the die's second conductive region D. The resulting structure is shown in FIG. 2, where the reference numbers shown in the figure are the same as previously described above. This attachment and conductive regions D and 26 collectively provide an electrical interconnection between semiconductor die 5 and a system that utilizes package 10. Next, wire-type conductive structure 30 is assembled onto package 10 such that a first portion 31 of the structure is attached and electrically coupled to the die's third conductive region G, and a second portion 32 of the structure is attached and electrically coupled to the leadframe's third conductive region 28. Wire-type conductive structure 30 may comprise a wire bond, a ribbon bond, a tape-automated bond (“TAB bond”), and the like. Conductive structure 30 and conductive regions G and 28 collectively provide another electrical interconnection between semiconductor die 5 and a system that utilizes package 10.

Next in the exemplary method, as shown in FIG. 3, electrically conductive spring structure 40 is assembled with semiconductor die 5 and leadframe 20 such that a first portion 41 of the spring structure 40 faces and contacts the die's first electrically conductive region S, and a second portion of spring structure 40 faces and contacts the leadframe's first electrically conductive region 24. Spring structure 40 also has a third portion 43 located between the structure's first and second portions 41 and 42. In one implementation, spring structure 40 has a general U-shape (shown upside-down in FIG. 3), with portion 43 having two short sides and a long back side (which is the bottom of the U-shape). Other implementations of spring structure 40 are possible, and are described below. Spring structure 40 preferably comprises a core sheet of resilient elastic material, such as spring steel or a polymer, which is coated with at least one layer of electrically conductive material, such as aluminum (Al), copper (Cu), or gold (Au), with one or more optional barrier layers between it and the core sheet (such as nickel and palladium). The core sheet may be heated (to temporarily lower the sheet's elastic limit) and bent to shape to the desired shape, or in some cases may be stamped at room temperature to the desired shape with forces that exceed sheet's elastic limit. The other reference numbers described in FIG. 3 have been previously described with reference to FIGS. 1 and 2.

Next in the exemplary method, a force F is applied to spring structure 40 such that the structure's first portion 41 abuts and makes electrical connection with the die's first conductive region S, such that the structure's second portion 42 abuts and makes electrical connection with the leadframe's first conductive region 24, and such that the structure's third portion 43 is compressively strained, but preferably not stressed beyond its elastic limit. As is known in the materials science art, a structure is strained when it is distorted from its intrinsic shape by external or internal forces acting on it. In the exemplary spring structure shown in FIG. 3, force F is preferably applied to the long back side of portion 43 by a mold plate during a molding step, and the short sides of portion 43 are compressed and placed in a state of compressive strain. Before, during, or after the initiation of force F, a body of molding material, preferably in viscous form (i.e., liquid form), is disposed over spring structure 40, die 5, and leadframe 20 and allowed to undergo a transition from a liquid state to a solid state while force F is applied. After the molding material is solidified, force F may be removed. While currently not preferred, it is possible to initially dispose the molding material in a powdered form (i.e., solid particles, which may comprise a thermoplastic material), to thereafter heat the powder to turn it into a liquid form, and to thereafter allow the liquid form to solidify. The solidified molding material maintains the compressive strain state of portion 43, which in turn keeps first portion 41 in contact with the die's first electrically conductive region S and second portion 42 in contact with the leadframe's first electrically conductive region 24.

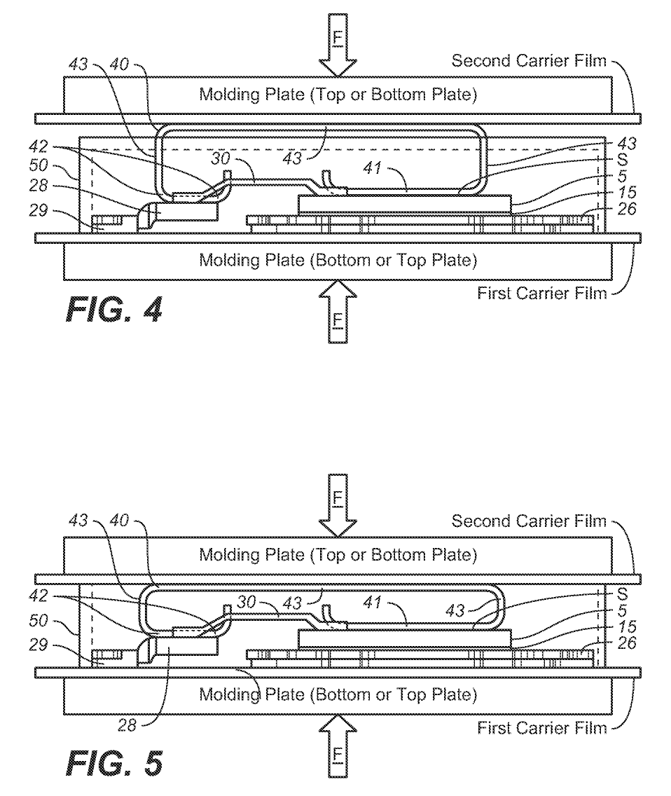

The latter steps of the exemplary method can be implemented using a dual-side, film-assisted molding process, which is illustrated by the side views of FIGS. 4 and 5, wherein the reference numbers shown therein have been previously described. Prior to the molding process, assembled instances of leadframe 20 and die 5 are releasably attached to a first carrier film (with leadframe 20 contacting the first carrier film), and instances of spring structure 40 are releasably attached to a second carrier film (with the back side of portion 43 contacting the second carrier film). As used herein, the state of “releasably attached” means that the carrier films may be later removed without damage to the finished package. Each carrier film may comprise a polymer sheet having dimensional stability that is coated with a releasable adhesive on one side. The first carrier film may be attached to a roll of leadframes 20 before or after the dice 5 are assembled with the leadframes, and may be attached so as to not interfere with the indexing apertures of the roll. (Typically, the first carrier film is already part of the roll, and no special step is needed.) Automated pick-and-place equipment may be used to assemble the spring structures 40 on to the second carrier film. Some molding equipment, such as that sold by Boschman Technologies, have pick-and-place capabilities. With such equipment, the second carrier film may be transported across the bottom molding plate without the need for indexing apertures, and each spring structure 40 may be disposed on the second carrier film while in the molding chamber, just prior to the molding operation. If such equipment is not available, the second carrier film may include indexing apertures to assist the pick-and-place equipment and the molding equipment with the alignment of the spring structures 40. In this latter approach, the second carrier film may be attached to a roll of leadframe carrier rings that have blank areas to receive the spring structures, and the spring structures may be attached to the blank areas by the pick-and-place equipment.

Both carrier films are then fed into a film-assisted molding machine. If spring structures 40 are already assembled on the second carrier film, then the carrier films are aligned with another so that portions 41 and 42 of spring structure 40 will face conductive regions 24 and S, respectively, when films are transported into the molding chamber. In this case, the first carrier film may be transported along either the top or bottom molding plate, and the second carrier film along the other molding plate. If the spring structures are not already assembled on the second carrier film, then the second carrier film is transported along the bottom molding plate, and a pick-and-place tool takes a spring structure from a stock source, and places it on the second carrier film in a predetermined position with respect to the bottom molding plate (the predetermined position may be inside the molding chamber or outside the molding chamber, such as at an up-stream assembly area next to the molding chamber). The first carrier film is transported along the top molding plate, and aligned to bring conductive regions 24 and S of leadframe 20 and die 5, respectively, into alignment with the structure's portions 41 and 42, respectively. Once in the molding chamber, as shown in FIG. 4, two molding plates press the carrier films toward one another to press spring structure 40 against leadframe 20 and die 5, causing the short sides of portion 43 of the spring structure to move outward and become compressively strained, and causing portions 41 and 42 to abut and make electrical contact with conductive regions 24 and S, respectively, as shown in FIG. 5. Before, during, or after the molding plates are pressed together, a body 50 of molding material is injected into the space between the carrier films, and covers at least portions of leadframe 20, die 5, and spring structure 40, and preferably covers all of these components once the plates are at their compressed positions. The molding plates are preferably held in their compressed positions until body 50 solidifies. After body 50 solidifies, the plates are retracted, and the carrier films are moved to position the next instance into the mold. Several instances of package 10 may be processed in this manner.

If molding material is initially present in the gap between portion 41 (or 42) and conductive region 24 (or S), the pressing of the portion against the conductive region closes the gap and ejects the molding material to enable an electrical coupling to be made. To minimize the changes of any remaining molding material degrading the electrical coupling, one or more of the following actions may be taken: (1) the second carrier film may be transported along the bottom molding plate, (2) the molding material may be disposed along one or more sides of spring structure 40, and (3) portions 41-42 and conductive regions 24, S may be brought into at least light contact before the molding material is dispensed.

In the above way, an electrical connection may be made between conductive region S of die 5 and conductive region 24 of leadframe 20 within an existing molding operation, and with the addition of simple, fast, and inexpensive pick-and-place operation. The previously-used fluxing, soldering, and cleaning operations are thus eliminated, with a substantially savings is time and cost.

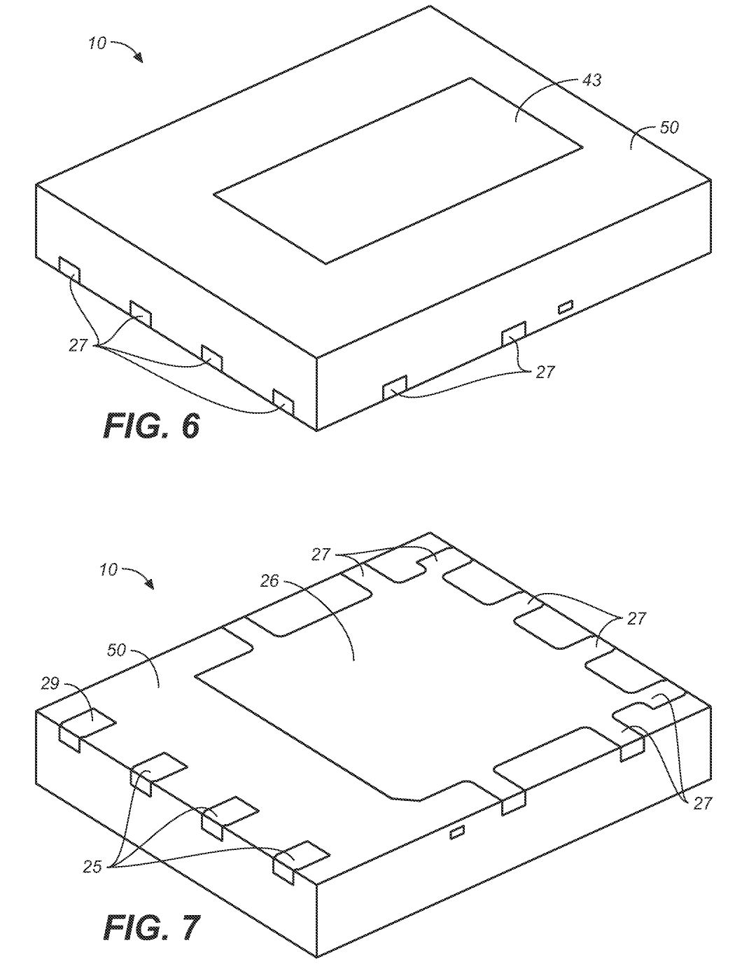

After processing, the carrier films are peeled away from the package instances, and the instances are trimmed of excess material. The final outline of the package's side dimensions, after molding and trimming, is shown by the dashed rectangles in FIGS. 4 and 5. FIG. 6 shows a top perspective view of the completed package 10, and FIG. 7 shows a bottom perspective view. There it can be seen that end caps 25, 27, and 29 are exposed, that conductive region 26 is exposed (which can enhance thermal conduction and cooling of package 10), and that the back side of spring portion 43 is exposed, which can provide an additional electrical connection point.

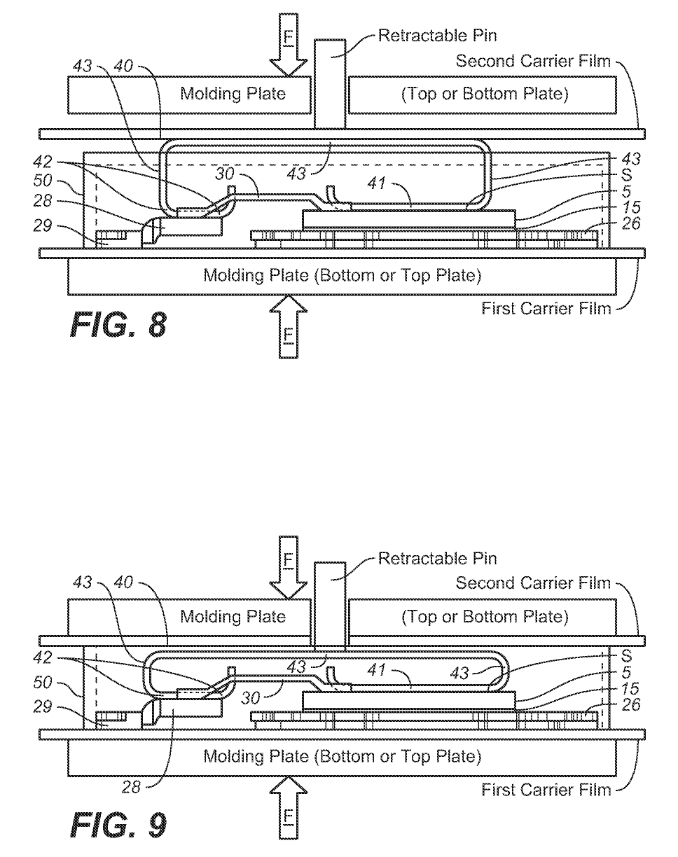

In some applications of package 10, it is preferred that the back side of spring portion 43 is not exposed. This can be achieved by using one or more retractable pins during the mold transfer process, as illustrated by a second exemplary embodiment in FIGS. 8 and 9, where the reference numbers shown therein have been previously described. Each retractable pin compresses the spring clip during the molding process, and is then retracted just before the molding material fully sets (e.g., fully cures), preferably at a stage where the material is soft enough to allow the pin to retract, but firm enough to hold the spring portion 43 in a compressive strained state. Each pin will leave a small, characteristic aperture in the molding material, and this aperture typically has uneven side walls (because the pin is retracted when the material is not fully set) and/or will have vertical streak marks caused by burrs on pin. The first carrier film may have an aperture formed in it for each retractable pin. The retractable pins may be coated with a non-stick material. As a result, the back side of portion 43 is covered by molding material, and is not exposed.

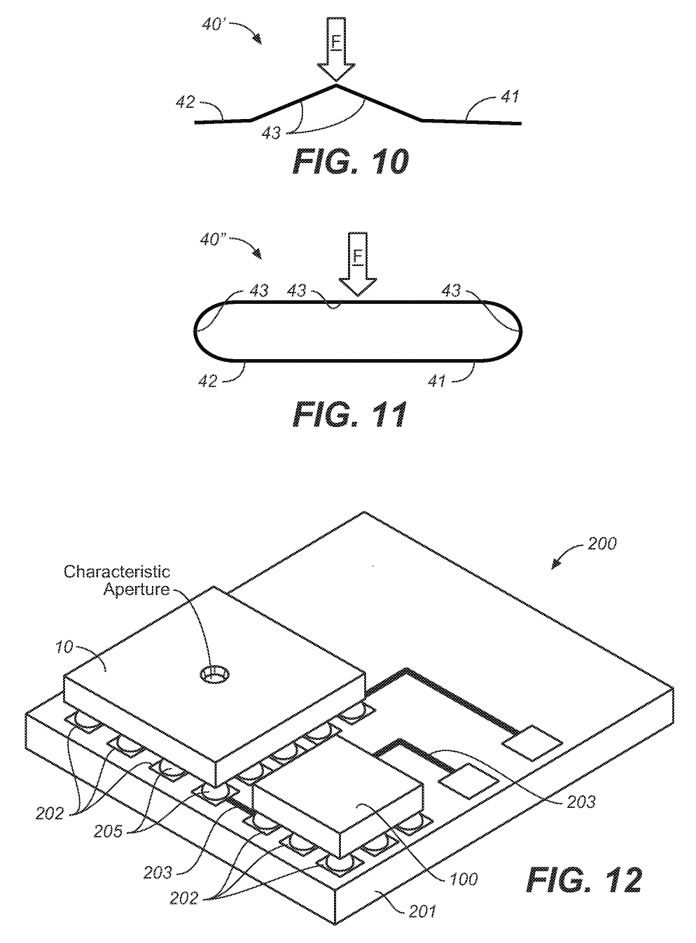

Spring structures according to the present invention may have shapes that are different from the U-shape illustrated above. FIG. 10 shows a spring structure 40′ with a portion 43 that has a shallow V-shape, and FIG. 11 shows a spring structure 40″ that has an oval shape. Each has portions 41 and 42 that provide electrical connections, and a portion 43 that is compressively strained. For each of spring structures 40, 40′, 40″, and variations thereof, each of their portions 41 and 42 exerts a force against the opposing conductive (e.g., regions 24 and S, respectively) that is greater than the portion's gravitational force (i.e., weight), and that is preferably greater than the gravitational force of the spring structure. While the present invention has been illustrated with one spring structure per semiconductor die package, it may be appreciated that multiple spring structures may be used per package.

FIG. 12 shows a perspective view of a system 200 that comprises semiconductor package 10 according to the present invention. System 200 comprises an interconnect substrate 201, a plurality of interconnect pads 202 to which components are attached, a plurality of interconnect traces 203 (only a few of which are shown for the sake of visual clarity), an instance of package 10, second package 100, and a plurality of solder bumps 205 that interconnect the packages to the interconnect pads 202. Package 10 is shown with the aforementioned characteristic aperture.

The semiconductor die packages described above can be used in electrical assemblies including circuit boards with the packages mounted thereon. They may also be used in systems such as phones, computers, etc.

Some of the examples described above are directed to “leadless” type packages such as MLP-type packages (microleadframe packages) where the terminal ends of the leads do not extend past the lateral edges of the molding material. Embodiments of the invention may also include leaded packages where the leads extend past the lateral surfaces of the molding material.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. A semiconductor die package comprising:
a leadframe having a first electrically conductive region;
a semiconductor die having a first surface, a second surface, a first electrically conductive region disposed on the die's first surface, the die's second surface being attached to a portion of the leadframe;
a first electrically conductive structure having a first portion abutting the die's first electrically conductive region, a second portion abutting the leadframe's first electrically conductive region, and a third portion located between the structure's first and second portions, the third portion being compressively strained; and
a body of molding material disposed over at least a portion of the first electrically conductive structure, over at least a portion of the die's first surface, and at least portions of the leadframe's first and second electrically conductive regions.

2. The semiconductor die package of claim 1 wherein the third portion of the spring structure imparts a force to each of the first and second portions of the spring structure.

3. The semiconductor die package of claim 2 wherein the first portion of the spring structure imparts a force against the die's first electrically conductive region that is greater than the gravitation force of the first portion, and wherein the second portion of the spring structure imparts a force against the leadframe's first electrically conductive region that is greater than the gravitation force of the second portion.

4. The semiconductor die package of claim 2 wherein the first portion of the spring structure imparts a force against the die's first electrically conductive region that is greater than the gravitation force of the spring structure, and wherein the second portion of the spring structure imparts a force against the leadframe's first electrically conductive region that is greater than the gravitation force of the spring structure.

5. The semiconductor die package of claim 1 wherein there is no solder material disposed between the first portion of the spring structure and the die's first electrically conductive region, and no solder material disposed between the second portion of the spring structure and the leadframe's first electrically conductive region.

6. The semiconductor die package of claim 1 wherein the third portion of the spring structure comprises a long back side and two short sides, each short side having a length shorter than the long back side, and each short side being disposed between the long back side and one of the first and second portions of the spring structure.

7. The semiconductor die package of claim 1 wherein the third portion of the spring structure comprises two sides configured in a V-shape.

8. The semiconductor die package of claim 1 wherein the spring structure further comprises an oval shape.

9. The semiconductor die package of claim 1 wherein the spring structure further comprises a core sheet of resilient elastic material that is coated with at least one layer of electrically conductive material.

10. The semiconductor die package of claim 9 wherein the resilient elastic material comprises at least one of spring steel or a polymer.

11. The semiconductor die package of claim 1 wherein the leadframe further comprises a second electrically conductive region, and wherein the semiconductor die further comprises a second electrically conductive region disposed on the die's second surface, the die's second electrically conductive region being disposed over a portion of the leadframe's second conductive region and electrically coupled thereto.

12. The semiconductor die package of claim 11 wherein the leadframe further comprises a third electrically conductive region, wherein the semiconductor die further comprises a second electrically conductive region disposed on the die's first surface, and wherein the semiconductor die package further comprises a conductive wire-type structure having a first portion electrically coupled to the leadframe's third electrically conductive region, a second portion electrically coupled to the die's third electrically conductive region, and a third portion disposed between the first and second portions of the wire-type structure.

13. A system comprising a substrate and the semiconductor die package of claim 1 attached to the substrate.

14. A method comprising:
attaching a semiconductor die to a portion of a leadframe, the die having an exposed first conductive region, the leadframe having an exposed first conductive region;
assembling an electrically conductive spring structure with the die and leadframe such that a first portion of the spring structure at least faces the die's first electrically conductive region, and a second portion of the spring structure at least faces the leadframe's first electrically conductive region, the spring structure having a third portion located between the structure's first and second portions;
applying a force to the spring structure such that the structure's first portion abuts the die's first conductive region, the structure's second portion abuts the leadframe's first conductive region, and the structure's third portion is compressively strained;
disposing a molding material over at least a portion of the spring structure, at least a portion of the die, and at least a portion of the leadframe; and
maintaining the application of said force while the molding material undergoes a transition from a liquid state to a solid state.

15. The method of claim 14 wherein the molding material is disposed before the initiation of said force.

16. The method of claim 14 wherein the molding material is disposed after the initiation of said force.

17. The method of claim 14 wherein the leadframe and semiconductor die are assembled and releasably attached to a first carrier film with the leadframe contacting the first carrier film, and wherein assembling the spring structure with the die and leadframe further comprises:
releasably attaching the spring structure on to a second carrier film;
aligning the carrier films; and
placing the carrier films in a molding chamber, wherein the carrier films are aligned to one another such that the spring structure's first portion faces the die's first conductive region and the spring structure's second portion faces the leadframe's first conductive region when the films are in the molding chamber.

18. The method of claim 17 wherein the molding chamber comprises two molding plates disposed at respective outer surfaces of the carrier films, and wherein applying a force to the spring structure comprises moving two molding plates toward one another.

19. The method of claim 18 wherein applying a force to the spring structure further comprises applying a force to the spring structure with a pin whose position can be retracted with respect to one of the molding plates.

20. The method of claim 19 wherein maintaining the application of said force while the molding material undergoes a transition from a liquid state to a solid state comprises retracting the pin after the molding material is sufficiently firm to hold the third portion of the spring structure in a compressive strained state.

21. The method of claim 20 further comprising retracting the pin before the molding material is fully solidified.

22. The method of claim 14 wherein the leadframe and semiconductor die are assembled and releasably attached to a first carrier film with the leadframe contacting the first carrier film, and wherein assembling the spring structure with the die and leadframe further comprises:
disposing a second carrier film on the bottom plate of a molding chamber;
placing the spring structure on a second carrier film in a predetermined position with respect to the bottom molding plate of a molding chamber; and
positioning the first carrier film over the spring structure.

23. The method of claim 22 wherein the molding chamber further comprises a top molding plate disposed over the first carrier film, and wherein applying a force to the spring structure comprises moving two molding plates toward one another.

24. The method of claim 23 wherein the predetermined position is at an assembly area next to the molding chamber.

25. The method of claim 22 wherein applying a force to the spring structure further comprises applying a force to the spring structure with a pin whose position can be retracted with respect to the bottom molding plate.

26. The method of claim 25 wherein maintaining the application of said force while the molding material undergoes a transition from a liquid state to a solid state comprises retracting the pin after the molding material is sufficiently firm to hold the third portion of the spring structure in a compressive strained state, but before the molding material fully solidifies.
